(19) United States
(12) Patent Application Publication
(10) Pub. No.: US 2025/0259938 A1
(43) Pub. Date: Aug. 14, 2025

(54) SEMICONDUCTOR PACKAGE

(71) Applicant: Samsung Electronics Co., Ltd., Suwon-si (KR)

(72) Inventors: Dongchul Yang, Suwon-si (KR); Younghun Jung, Suwon-si (KR)

(21) Appl. No.: 18/940,775

(22) Filed: Nov. 7, 2024

(30) Foreign Application Priority Data
Feb. 13, 2024 (KR) 10-2024-0020211

(51) Int. Cl. H01L 23/538; H01L 23/00; H01L 23/498; H01L 25/065; H10B 80/00

(52) U.S. Cl. CPC H01L 23/5386; H01L 23/49816; H01L 23/5383; H01L 25/0655; H01L 24/16; H01L 24/32; H01L 24/73; H01L 2224/16227; H01L 2224/32225; H01L 2224/73204; H10B 80/00

(57) ABSTRACT

A semiconductor package includes a package substrate, a first chip structure including a first semiconductor chip and a second semiconductor chip, and a second chip structure. The first semiconductor chip has a first front surface and a first back surface opposing each other. The first semiconductor chip includes a first front circuit layer and a first back circuit layer, first front connection pads and first back connection pads respectively disposed on upper portions of the first front surface and the first back surface, and through-electrodes including a first through-electrode electrically connecting the first front circuit layer and the first back circuit layer to each other, and a second through-electrode electrically connecting at least a portion of the first front connection pads and the first back circuit layer to each other.

### CROSS-REFERENCE TO RELATED APPLICATION(S)

This application claims benefit of priority to Korean Patent Application No. 10-2024-0020211 filed on Feb. 13, 2024 in the Korean Intellectual Property Office, the disclosure of which is incorporated herein by reference in its entirety.

### BACKGROUND

The present inventive concept relates to a semiconductor package. With reductions in weight and the implementation of high performance in electronic devices, the development of semiconductor packages, having a reduced size and high performance, has been required. As the numbers of circuits provided in semiconductor devices increase, the congestion of integrated circuits has been increased, which can lead to issues in the smooth delivery of power to such integrated circuits. Accordingly, technologies have been emerging to improve lowered voltage properties.

### SUMMARY

An aspect of the present inventive concept provides a semiconductor package having improved voltage properties.

According to an aspect of the present inventive concept, there is provided a semiconductor package including a package substrate having an upper surface and a lower surface opposing each other, a first chip structure disposed on the upper surface of the package substrate, the first chip structure including a first semiconductor chip, a second semiconductor chip disposed on the first semiconductor chip, microbumps electrically connecting the first and second semiconductor chips to each other, and an adhesive layer covering at least a portion of the microbumps between the first and second semiconductor chips, and a second chip structure spaced apart from the first chip structure, on the upper surface of the package substrate. The first semiconductor chip may have a first front surface and a first back surface opposing each other. The first semiconductor chip may include a first front circuit layer and a first rear circuit layer respectively disposed to be adjacent to the first front surface and the first back surface, first front connection pads and first back connection pads respectively disposed on upper portions of the first front surface and the first back surface, and through-electrodes including a first through-electrode electrically connecting the first front circuit layer and the first back circuit layer to each other, and a second through-electrode electrically connecting at least a portion of the first front connection pads and the first back circuit layer to each other. The second semiconductor chip may have a second front surface opposing the first front surface. The second semiconductor chip may include a second front circuit layer disposed to be adjacent to the second front surface, and second front connection pads disposed on the second front surface.

According to another aspect of the present inventive concept, there is provided a semiconductor package including a package substrate having a surface, the surface having a first side and a second side opposite the first side, the semiconductor package including a first chip structure disposed on the surface of the package substrate and adjacent to the first side of the surface, the first chip structure including a first semiconductor chip and a second semiconductor chip stacked on the first semiconductor chip, and a second chip structure disposed on the surface of the package substrate and adjacent to the second side of the surface, the second chip structure spaced apart from the first chip structure. The first semiconductor chip may include a first substrate, a first front circuit layer disposed on the first substrate, the first front circuit layer including a first integrated circuit, and a plurality of first and second through-electrodes passing through the first substrate. The second semiconductor chip may include a second front circuit layer disposed toward the first front circuit layer of the first semiconductor chip, the second front circuit layer including a second integrated circuit. A portion of the first through-electrodes may be configured to transmit power and ground signals of the first integrated circuit. The second through-electrodes may be configured to transmit power and ground signals of the second integrated circuit.

According to another aspect of the present inventive concept, there is provided a semiconductor package including a first semiconductor chip including a first front circuit layer and a first back circuit layer respectively disposed to be adjacent to a first front surface and a first back surface opposing each other, a plurality of first front connection pads and first back connection pads respectively disposed on the first front circuit layer and the first back circuit layer, and a plurality of first and second through-electrodes electrically connected to the first back circuit layer, a second semiconductor chip including a second front circuit layer disposed to be adjacent to the first front circuit layer of the first semiconductor chip, and a plurality of second front connection pads disposed on the second front circuit layer, microbumps disposed between the first front connection pads and the second front connection pads, an adhesive layer disposed between the first and second semiconductor chips, the adhesive layer covering at least a portion of each of the first semiconductor chip, the second semiconductor chip, and the microbumps, and connection bumps disposed below the first semiconductor chip. The first semiconductor chip may be configured to receive power through the plurality of first through-electrodes. The second semiconductor chip may be configured to receive power through the plurality of second through-electrodes. A pitch of the connection bumps may be greater than a pitch of the microbumps.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view of a semiconductor package according to an example embodiment of the present inventive concept;

FIG. 2 is a cross-sectional view according to an example embodiment of a first chip structure applicable to the semiconductor package of FIG. 1;

FIG. 3 is a partially enlarged view of region “A” of FIG. 2 of a semiconductor package according to an example embodiment of the present inventive concept;

FIG. 4 is a partially enlarged view of region “B” of FIG. 2 of a semiconductor package according to an example embodiment of the present inventive concept;

FIG. 5 is a cross-sectional view of a semiconductor package according to an example embodiment of the present inventive concept;

FIG. 6 is a cross-sectional view of a semiconductor package according to an example embodiment of the present inventive concept; and

FIG. 7 is a cross-sectional view of a semiconductor package according to an example embodiment of the present inventive concept.

### DETAILED DESCRIPTION

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that-examples-and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail-it is impracticable to list every possible variation for every feature described herein. The language of the claims should be referenced in determining the requirements of the invention.

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

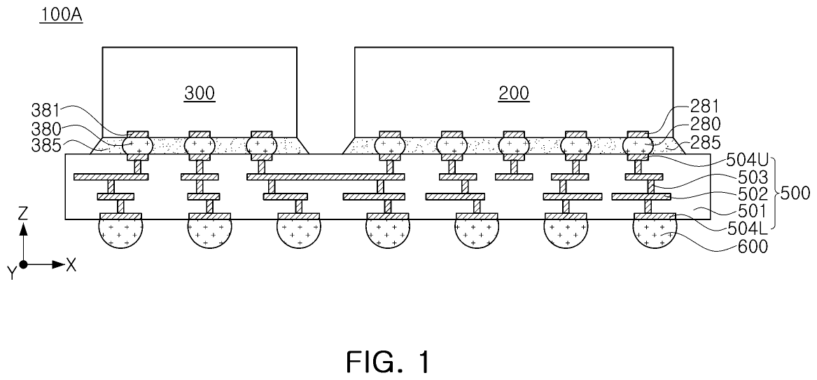

FIG. 1 is a cross-sectional view of a semiconductor package according to an example embodiment of the present inventive concept.

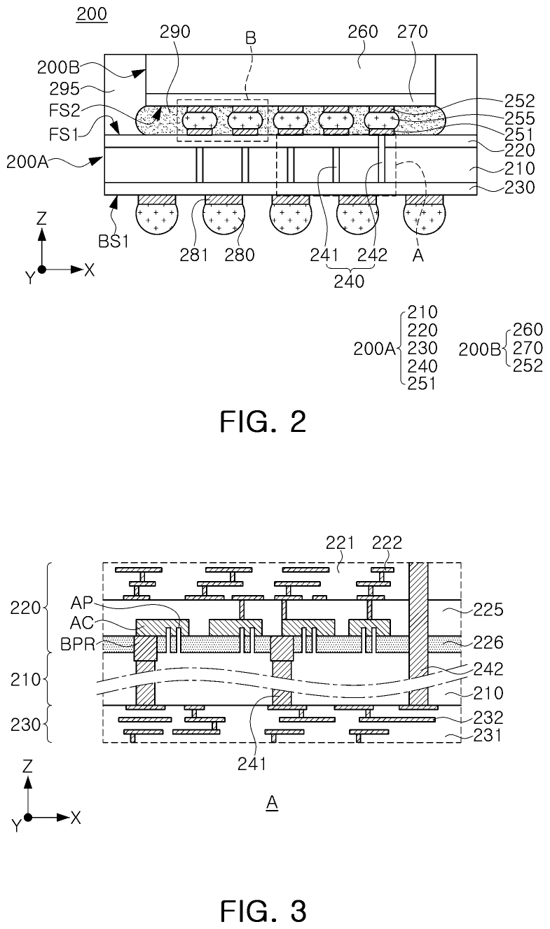

FIG. 2 is a cross-sectional view according to an example embodiment of a first chip structure applicable to the semiconductor package of FIG. 1.

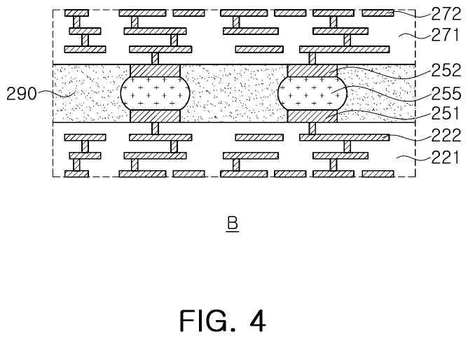

Referring to FIGS. 1 to 4, a semiconductor package 100A according to an example embodiment may include a package substrate 500, a first chip structure 200, a second chip structure 300, first connection bumps 280, second connection bumps 380, and underfill portions 285 and 385. Referring to FIG. 1, the semiconductor package 100A according to an example embodiment may further include external connection conductors 600.

The package substrate 500 may have an upper surface and a lower surface opposing each other, and may include an insulating layer 501, an interconnection layer 502, an interconnection via 503, upper connection pads 504U, and lower connection pads 504L. The package substrate 500 may be a substrate for a semiconductor package, including a printed circuit board (PCB), a ceramic substrate, a glass substrate, a tape interconnection substrate, or the like. In an example embodiment, the package substrate 500 may be an organic substrate.

The insulating layer 501 may include an insulating resin. The insulating resin may include a thermosetting resin such as an epoxy resin, a thermoplastic resin such as polyimide, or a resin in which the thermosetting resin or the thermoplastic resin is impregnated with an inorganic filler and/or a glass fiber (or glass cloth or glass fabric), for example, a prepreg, an Ajinomoto build-up film (ABF), FR-4, bismaleimide triazine (BT). The insulating resin may include a photosensitive resin such as a photoimageable dielectric (PID). For example, when the package substrate 500 is a PCB substrate, the insulating layer 501 may be a core insulating layer (for example, a prepreg) of a copper clad laminate. The insulating layer 501 may have a form in which a large number of insulating layers are stacked in a vertical direction (Z-direction), and first insulating layers on different levels may have unclear boundaries therebetween depending on a process.

The interconnection layer 502 may be disposed within the insulating layer 501, and may form an electrical path within the package substrate 500. The interconnection layer 502 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). The interconnection layer 502 may be a plurality of interconnection layers 502 positioned on different levels, between the plurality of insulating layers 501. A plurality of interconnection vias 503 may connect the plurality of interconnection layers 502, positioned on different levels, to each other, and may include a material the same as that of the plurality of interconnection vias 503.

The upper connection pads 504U may be electrically connected to at least one of the first connection bumps 280 of the first chip structure 200 and the second connection bumps 380 of the second chip structure 300, on an upper portion of the insulating layer 501. The lower connection pads 504L may be electrically connected to a plurality of external connection conductors 600, on a lower portion of the insulating layer 501. As used herein, components described as being “electrically connected” are configured such that an electrical signal can be transferred from one component to the other (although such electrical signal may be attenuated in strength as it is transferred and may be selectively transferred). The upper connection pads 504U and the lower connection pads 504L may include materials the same as those of the interconnection layers 502 and the interconnection vias 503.

In some example embodiments, a protective layer may be disposed on an upper surface and/or a lower surface of the package substrate 500. The protective layer may serve to protect the interconnection layer 502 from external physical/chemical damage, on an uppermost and/or lowermost insulating layer 501 among the plurality of insulating layers 501. The protective layer may be a solder resist layer. The solder resist layer may include an insulating material, and may be formed using, for example, a prepreg, an ABF, FR-4, BT, or a photo solder resist (PSR).

Referring to FIGS. 2 to 4, the first chip structure 200 may be disposed on the package substrate 500, and may include a plurality of semiconductor chips 200A and 200B stacked in the vertical direction (for example, a Z-axis direction). At least a portion (for example, “200A”) of the plurality of semiconductor chips 200A and 200B may include through-vias electrically connecting the plurality of semiconductor chips 200A and 200B to each other. The through-vias described herein may be through substrate vias that extend through the substrate of a chip (the base, initial substrate, such as silicon on insulator (SOI), bulk silicon or other crystalline semiconductor) or fully through a chip to provide signal and/or power connections from the backside of the chip to chip pads or other terminals on the front side of the chip formed with the active surface of the chip. The plurality of semiconductor chips 200A and 200B may be chiplets included in a multi-chip module (MCM). The plurality of semiconductor chips 200A and 200B may include a central processing unit (CPU), a graphics processing unit (GPU), a field programmable gate array (FPGA), a digital signal processor (DSP), a cryptographic processor, a microprocessor, a microcontroller, an analog-digital converter, an application-specific integrated circuit (ASIC), a volatile memory, a non-volatile memory, an input/output (I/O) circuit, an analog circuit, a serial-parallel conversion circuit, and the like.

The first chip structure 200 may include a first semiconductor chip 200A and a second semiconductor chip 200B. The first semiconductor chip 200A may include a processor circuit, and the second semiconductor chip 200B may include at least one of an input/output circuit, an analog circuit, a memory circuit, and a serial-parallel conversion circuit for the processor circuit. A width of the first semiconductor chip 200A in a horizontal direction (for example, an X-axis direction) may be greater than a width of the second semiconductor chip 200B in the horizontal direction. In some example embodiments, the second semiconductor chip 200B may include a plurality of second semiconductor chips 200B spaced apart from each other in the horizontal direction (for example, X-axis direction), on the first semiconductor chip 200A.

The first chip structure 200 may include a first encapsulant 295 covering at least a portion of each of the first semiconductor chip 200A and the second semiconductor chip 200B. An adhesive layer 290 may be formed between the first semiconductor chip 200A and the second semiconductor chip 200B.

The first semiconductor chip 200A may have a first front surface FS1 and a first back surface BS1 opposing each other, and may include a first substrate 210, a first front circuit layer 220, a first back circuit layer 230, through-electrodes 240, first front connection pads 251, and first back connection pads 281. The second semiconductor chip 200B may be disposed on the first front surface FS1 of the first semiconductor chip 200A, and a plurality of connection bumps 280 may be disposed on the first back surface BS1 of the first semiconductor chip 200A.

The first substrate 210 may be crystalline semiconductor and include, for example, a semiconductor element such as silicon (Si) or germanium (Ge), or a compound semiconductor such as silicon carbide (SiC), gallium arsenide (GaAs), indium arsenide (InAs), or indium phosphide (InP). The first substrate 210 may be a silicon on insulator (SOI) substrate. The first substrate 210 may have a conductive region, for example, a well doped with impurities, or an active surface (the upper surface of first substrate 210 in FIG. 2) doped with impurities and an inactive surface (the lower surface of first substrate 210 in FIG. 2) opposite thereto. The active surface may include active patterns with which transistors are formed and interconnected to form logic circuits of the integrated circuit. The inactive surface may not be provided with (or used to form) transistors. The first substrate 210 may include various device isolation structures, such as a shallow trench isolation (STI) structure. The first front circuit layer 220 may be disposed on the active surface of the first substrate 210, and the first back circuit layer 230 may be disposed on the inactive surface of the first substrate 210.

The first front circuit layer 220 may be disposed on the active surface of the first substrate 210, and may include interlayer insulating layer(s) 221, an interconnection structure 222, an inter-metal dielectric (IMD) layer 225, and an oxide layer 226. The interlayer insulating layer(s) 221 may include flowable oxide (FOX), tonen silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high-density plasma (HDP) oxide, plasma enhanced oxide (PEOX), flowable CVD (FCVD) oxide, or combinations thereof. At least a portion of the interlayer insulating layer(s) 221, surrounding the interconnection structure 222, may include a low dielectric layer. The interlayer insulating layer(s) 221 may be formed using a chemical vapor deposition (CVD) process, a flowable CVD process, or a spin coating process. The first front circuit layer 220 may include a first integrated circuit. Transistors can be formed at the active surface of the first substrate 210 using active patterns AP (e.g., to form FinFETs or other types of transistors), and logic circuits for the first integrated circuit can be formed using such transistors.

The interconnection structure 222 may be disposed between the first substrate 210 and the first front connection pads 251, and may be buried in the interlayer insulating layer(s) 221. The interconnection structure 222 may have a multilayer structure including interconnection pattern(s) and via(s) formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film (not illustrated), including titanium (Ti), titanium nitride (TiN), tantalum (Ta), or tantalum nitride (TaN), may be disposed between the interconnection pattern or/and the via and the interlayer insulating layer(s) 221.

As shown in FIG. 2, the first semiconductor chip 200A and the second semiconductor chip 200B can be face-to-face with each other, such that the second front circuit layer 270 of the second semiconductor chip 200B faces down towards the first semiconductor chip 200A and the first front circuit layer 220 of the first semiconductor chip 200A faces up towards the second semiconductor chip 200B, while the first back circuit layer 230 faces down, away from the second semiconductor chip 200B.

The first back circuit layer 230 can provide a back side power delivery network for the first semiconductor chip 200A. The first back circuit layer 230 can include interlayer insulating layer(s) 231 and interconnection structure 232. The interconnection structure 232 can be formed on the inactive surface of the first substrate 210 in order to create the back side power delivery network.

The interlayer insulating layer(s) 231 can surround the interconnection structure 232. Examples of materials included in the interlayer insulating layer(s) 231 can include any of the example materials mentioned above in reference to interlayer insulating layers(s) 221. At least a portion of the interlayer insulating layer(s) 231 can include a low dielectric layer. The interlayer insulating layer(s) 231 may be formed using a CVD process, a flowable CVD process, or a spin coating process.

The interconnection structure 232 can be disposed between the first substrate 210 and the first back connection pads 281, and can be buried in the interlayer insulating layer(s) 231. The interconnection structure 232 can have a multilayer structure including interconnection pattern(s) and via(s) formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film (not illustrated), including titanium (Ti), titanium nitride (TiN), tantalum (Ta), or tantalum nitride (TaN), may be disposed between the interconnection pattern or/and the via and the interlayer insulating layer(s) 231.

A plurality of active patterns AP and a plurality of active contacts AC may be disposed on the first semiconductor chip 200A, and a power signal may be provided by buried power rails BPR connected to the plurality of active patterns AP and the plurality of active contacts AC. The buried power rails can electrically connect with the back side power distribution network of the first back circuit layer 230 via first through-electrodes 241. The oxide layer 226 can be disposed on the first substrate 210, and the plurality of active patterns AP can extend through the oxide layer 226. The plurality of active patterns AP can be fins, and can be formed via etching of substrate 210 or epitaxial growth from substrate 210. The IMD layer 225 can be disposed between the oxide layer 226 and the interlayer insulating layer(s) 221. The first semiconductor chip 200A and the second semiconductor chip 200B may receive power from the first back circuit layer 230 via different respective through-electrodes, such that integrated circuits of the first semiconductor chip 200A and the second semiconductor chip 200B may be dispersed to reduce defects. This arrangement can also support an increased pitch with respect to the connection bumps 280 that electrically connect first back connection pads 281 with the upper connection pads 504U of package substrate 500. In some examples, this may enable a design that forgoes the use of a redistribution layer (RDL) substrate on top of the second semiconductor chip 200B, beneath the first semiconductor chip 200A (e.g., between the first semiconductor chip 200A) and the package substrate 500, or both.

The through-electrodes 240 may include first through-electrodes 241 passing through the first substrate 210, the first through-electrodes 241 electrically connecting the first front circuit layer 220 and the first back circuit layer 230 to each other, and second through-electrodes 242 electrically connecting at least a portion of the first front connection pads 251 and the first back circuit layer 230 to each other. The through-electrodes 240 may include a via plug and a side barrier film surrounding a side surface of the via plug. The via plug may include, for example, tungsten (W), titanium (Ti), aluminum (Al), or copper (Cu), and may be formed using a plating process, a PVD process, or a CVD process. The side barrier film may include titanium (Ti), titanium nitride (TiN), tantalum (Ta), or tantalum nitride (TaN), and may be formed using a plating process, a PVD process, or a CVD process. A side insulating film (not illustrated), including an insulating material (for example, high aspect-ratio process (HARP) oxide) such as silicon oxide, silicon nitride, or silicon oxynitride, may be formed between the side barrier film and the first substrate 210.

The first through-electrodes 241 may electrically connect the first front circuit layer 220 and the first back circuit layer 230 to each other. The first through-electrodes 241 may extend in the vertical direction (for example, a Z-axis direction) from the first back circuit layer 230 to the first front circuit layer 220. A first portion of the first through-electrodes 241 may be configured to transmit power and ground signals of the first integrated circuit of the first front circuit layer 220. In some examples, electrical connections within the first semiconductor chip 200A can electrically connect the first portion of the first through-electrodes 241 to internal power supply circuitry of the first integrated circuit, and the internal power supply circuitry can regulate externally-supplied power to generate internal power for the power and ground signals of the first integrated circuit. A second portion of the first through-electrodes 241 may be configured to transmit an input/output signal of the first integrated circuit of the first front circuit layer 220. In some examples, electrical connections within the first semiconductor chip 200A can electrically connect the second portion of the first through-electrodes 241 to an input/output interface of the first integrated circuit, and the input/output interface can latch data, address, and control signals provided to the first integrated circuit and transmit data, address, and control signals from the first integrated circuit.

The second through-electrodes 242 may electrically connect at least a portion of the first front connection pads 251 and the first back circuit layer 230 to each other. The second through-electrodes 242 may extend in the vertical direction (for example, a Z-axis direction) from the first back circuit layer 230 to the first front connection pads 251. A first portion of the second through-electrodes 242 may be configured to transmit power and ground signals of a second integrated circuit of the second front circuit layer 270. In some examples, electrical connections within the second semiconductor chip 200B can electrically connect the first portion of the second through-electrodes 242 to an internal power supply circuit of the second integrated circuit, and the internal power supply can regulate externally-supplied power to generate internal voltages (the power and ground) to operate logic circuits of the second integrated circuit. A second portion of the second through-electrodes 242 may be configured to transmit an input/output signal of the second integrated circuit of the second front circuit layer 270. In some examples, electrical connections within the second semiconductor chip 200B can electrically connect the second portion of the second through-electrodes 242 to an input/output interface of the second integrated circuit, and the input/output interface can latch data, address, and control signals provided to the second integrated circuit and transmit data, address, and control signals from the second integrated circuit.

Although only one second through-electrode 242 is illustrated, the number of second through-electrodes 242 is not limited thereto. The first through-electrodes 241 and the second through-electrodes 242 may have the same diameter, but the present inventive concept is not limited thereto. The first through-electrodes 241 and the second through-electrodes 242 may have a diameter of about 5 μm or less, or about 4 μm or less, but the present inventive concept is not limited thereto. The first semiconductor chip 200A may be configured to receive power through a plurality of first through-electrodes 241, and the second semiconductor chip 200B may be configured to receive power through a plurality of second through-electrodes 242.

The plurality of connection pads 251 and 281 may include first front connection pads 251 disposed on the first front surface FS1, and first back connection pads 281 disposed on the first back surface BS1. The first front connection pads 251 and the first back connection pads 281 may include, for example, at least one of aluminum (Al), copper (Cu), nickel (Ni), tungsten (W), platinum (Pt), and gold (Au). The first back connection pads 281 may be connected to an integrated circuit or individual devices (not illustrated) within the first front circuit layer 220 through through-electrodes 240, or to the first front connection pads 251. The first front connection pads 251 and the first back connection pads 281 may include a signal pad, a power pad, and a ground pad.

The second semiconductor chip 200B may have a second front surface FS2 opposing the first front surface FS1 of the first semiconductor chip 200A, and may include a second substrate 260, a second front circuit layer 270, and second front connection pads 252.

The second substrate 260, the second front circuit layer 270, and the second front connection pads 252 of the second semiconductor chip 200B may have features the same as or similar to those of the first substrate 210, the first front circuit layer 220, and the first front connection pads 251 of the above-described first semiconductor chip 200A, and thus a detailed description of the second substrate 260, the second front circuit layer 270, and the second front connection pads 252 may be found by reference to the above description of the first substrate 210, the first front circuit layer 220, and the first front connection pads 251 illustrated in FIGS. 2 to 4.

Microbumps 255 may be disposed between first front connection pads 251 disposed on the first front surface FS1 of the first semiconductor chip 200A and second front connection pads 252 disposed on the second front surface FS2 of the second semiconductor chip 200B. The microbumps 255 may be connection bumps that electrically connect the first semiconductor chip 200A and the second semiconductor chip 200B to each other. The microbumps 255 may include, for example, tin (Sn) or an alloy (for example, Sn—Ag—Cu) including tin (Sn). In some example embodiments, the microbumps 255 may be in the form of a combination of a metal pillar and a solder ball. In some examples, the microbumps 255 can be bumps of a smaller size and/or pitch than other bumps in semiconductor package 100A, such as first and second connection bumps 280 and 380. In some examples, a pitch of the microbumps 255 may be about 10 μm to 40 μm. In some examples, a width of the microbumps 255 may be about 5 μm to 20 μm. In some examples, the width of the microbumps 255 may be about half of the pitch of the microbumps 255.

The adhesive layer 290 may be disposed between the first semiconductor chip 200A and the second semiconductor chip 200B. The adhesive layer 290 may fill a space between the first semiconductor chip 200A and the second semiconductor chip 200B, and may surround at least a portion of each of the first front connection pads 251, the second front connection pads 252, and the microbumps 255. The adhesive layer 290 may be in contact with a side surface of each of the first front connection pads 251, the second front connection pads 252, and the microbumps 255. The adhesive layer 290 may be a non-conductive film (NCF), but the present inventive concept is not limited thereto, and may include, for example, any type of polymer film on which a heat compression process is performable.

The first encapsulant 295 may cover at least a portion of each of the first semiconductor chip 200A, the second semiconductor chip 200B, and the adhesive layer 290. The first encapsulant 295 may cover at least a portion of an upper surface of the first semiconductor chip 200A, and the first encapsulant 295 may cover at least a portion of a side surface of the second semiconductor chip 200B. An upper surface of the first encapsulant 295 may be coplanar with an upper surface of the first chip structure 200. The first encapsulant 295 may include an insulating resin, for example, a thermosetting resin such as an epoxy resin, a thermoplastic resin such as polyimide, or a prepreg, an ABF, FR-4, BT, or an epoxy molding compound (EMC). For example, the first encapsulant 295 may include a filler dispersed in the insulating resin.

The second chip structure 300 may be disposed on an upper surface of the package substrate 500, and may be spaced apart from the first chip structure 200 in the horizontal direction (for example, an X-axis direction). The second chip structure 300 may include at least one memory chip. The second chip structure 300 may be a bare semiconductor chip without a bump or an interconnection layer, but the present inventive concept is not limited thereto, and may be a packaged-type semiconductor chip. Specifically, the packaged-type semiconductor chip may include a base chip, a plurality of chips vertically stacked on the base chip, and a sealant covering the chip structure, on the base chip. The plurality of chips may include memory chips or memory devices storing or outputting data, based on an address command and a control command received from the base chip. For example, the plurality of semiconductor chips may include volatile memory devices such as DRAM and SRAM, or non-volatile memory devices such as PRAM, MRAM, FeRAM, or RRAM. The plurality of chips may include a first chip, at least one second chip, and a third chip, sequentially stacked on the base chip. For example, the base chip may be a buffer chip including a plurality of logic devices and/or memory devices in a device layer thereof. Accordingly, the buffer chip may externally transmit signals from a plurality of chips stacked on an upper portion thereof, and may also transmit external signals and power to the plurality of chips. The buffer chip may perform both a logic function and a memory function through the logic devices and the memory devices. However, in some example embodiments, the buffer chip may include only the logic devices, and may perform only the logic function.

The plurality of connection bumps 280 and 380 may include first connection bumps 280 electrically connected to the first chip structure 200 disposed on one side of the upper surface of the package substrate 500, and second connection bumps 380 electrically connected to the second chip structure 300 disposed on the other side of the upper surface of the package substrate 500. The connection bumps 280 and 380 may include, for example, tin (Sn), indium (In), bismuth (Bi), antimony (Sb), copper (Cu), silver (Ag), zinc (Zn), lead. (Pb) and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like. In some example embodiments, the connection bumps 280 and 380 may be in the form of a combination of a metal pillar and a solder ball. A pitch of the first connection bumps 280 may be greater than a pitch of the microbumps 255 that electrically connect the first semiconductor chip 200A and the second semiconductor chip 200B to each other. In some examples, the pitch of the first connection bumps 280 may be about 75 μm to 200 μm, or 50 μm to 225 μm.

The underfill portions 285 and 385 may be disposed to surround the connection bumps 280 and 380 respectively disposed at lower ends of the first and second chip structures 200 and 300, between the package substrate 500 and the first chip structure 200 and between the package substrate 500 and the second chip structure 300. The underfill portions 285 and 385 may fix the connection bumps 280 and 380 to the package substrate 500 to physically and electrically protect the connection bumps 280 and 380. The underfill portions 285 and 385 may have a shape having a width gradually increasing from the first and second chip structures 200 and 300 toward the upper surface of the package substrate 500. The underfill portions 285 and 385 may include a known insulating resin such as an epoxy resin. The underfill portions 285 and 385 may have a capillary underfill (CUF) structure, but the present inventive concept is not limited thereto.

The external connection conductors 600 may be disposed on the lower surface of the package substrate 500. The external connection conductors 600 may be electrically connected to the interconnection layers 502 and the lower connection pads 504L. The external connection conductors 600 may be bumps formed of a conductive material having a shape of a ball, a pin, or the like. The external connection conductors 600 may be, for example, solder balls. The external connection conductors 600 may electrically connect the semiconductor package 100A to an external device (for example, a motherboard). The external connection conductors 600 may be electrically connected to the first chip structure 200 or the second chip structure 300 through the interconnection layers 502.

In some example embodiments, at least one passive device (not illustrated) may be disposed below the package substrate 500. The passive device may be, for example, a capacitor, an inductor, a resistor, and the like. The passive device may be bonded to the lower surface of the package substrate 500 in a flip-chip manner. The passive device may be electrically connected to the interconnection layers 502 through a solder bump or the like. An underfill resin may be filled in a space between the passive device and the package substrate 500.

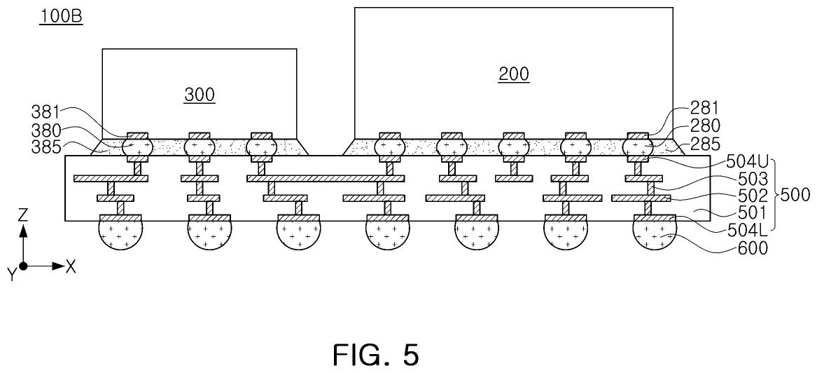

FIG. 5 is a cross-sectional view of a semiconductor package 100B according to an example embodiment of the present inventive concept.

Referring to FIG. 5, the semiconductor package 100B according to an example embodiment may have features the same as or similar to those described with reference to FIGS. 1 to 4, except that a height of a first chip structure 200 is higher than a height of a second chip structure 300. The first chip structure 200 may include a first semiconductor chip 200A and a second semiconductor chip 200B stacked on the first semiconductor chip 200A, and a height of the second semiconductor chip 200B may be higher than a height of the first semiconductor chip 200A. The first and second semiconductor chips 200A and 200B may be disposed to have a structure in which a first front surface FS1 and a second front surface FS2 oppose each other. A redistribution substrate may not need to be disposed on the first chip structure 200. Accordingly, the second semiconductor chip 200B, disposed on an upper portion of the first chip structure 200, may have no height restriction, and may have an increased height, as compared to the second semiconductor chip 200B in FIGS. 1 to 4.

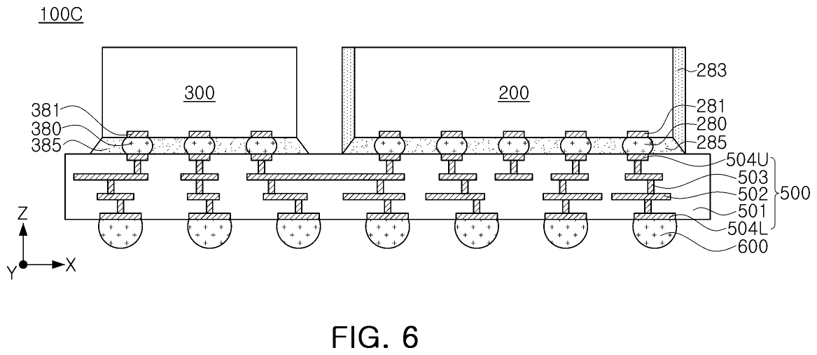

FIG. 6 is a cross-sectional view of a semiconductor package 100C according to an example embodiment of the present inventive concept.

Referring to FIG. 6, the semiconductor package 100C according to an example embodiment may have features the same as or similar to those described with reference to FIGS. 1 to 5, except that the semiconductor package 100C further includes a second encapsulant 283 surrounding a first chip structure 200. In an example embodiment, the second encapsulant 283 may be disposed to surround at least a portion of a side surface of the first chip structure 200. The second encapsulant 283 may be in contact with a side surface of a first semiconductor chip 200A, and the second encapsulant 283 may be in contact with a side surface of a first encapsulant 295 disposed on at least a portion of the first semiconductor chip 200A. The second encapsulant 283 may include a material the same as that of the first encapsulant 295. The second encapsulant 283 may be in contact with at least a portion of an underfill 285. In the semiconductor package 100C according to the present example embodiment, the second encapsulant 283, surrounding at least a portion of the side surface of the first chip structure 200, may be additionally introduced, thereby improving thermal properties.

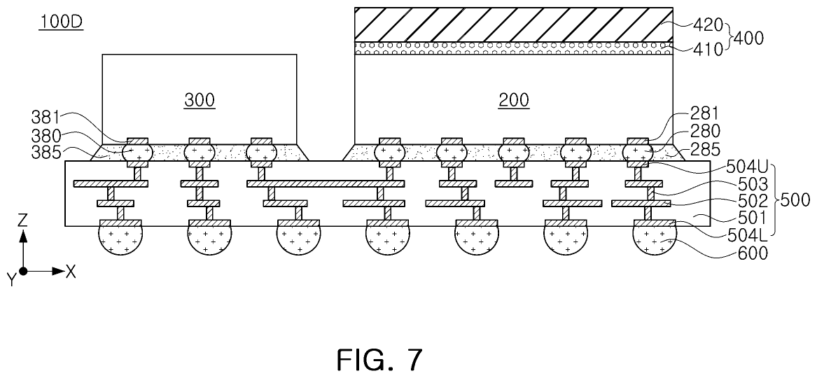

FIG. 7 is a cross-sectional view of a semiconductor package 100D according to an example embodiment of the present inventive concept.

Referring to FIG. 7, the semiconductor package 100D according to an example embodiment may have features the same as or similar to those described with reference to FIGS. 1 to 6, except that the semiconductor package 100D further includes a heat dissipation member 400, on a first chip structure 200. The heat dissipation member 400 may be disposed on an upper surface of the first chip structure 200. The heat dissipation member 400 may control warpage of the semiconductor package 100D, and may externally dissipate heat generated in the first chip structure 200. The heat dissipation member 400 may include a thermal interface material (TIM) layer 410 and a heat slug 420. The TIM layer 410 may be in contact with the upper surface of the first chip structure 200, specifically, an upper surface of each of a second semiconductor chip 200B and a first encapsulant 295. The TIM layer 410 may be, for example, a thermally conductive adhesive tape, thermally conductive grease, a thermally conductive adhesive, or the like. The heat slug 420 may be disposed on the TIM layer 410, and may be thermally connected with the upper surface of the first chip structure 200 via the TIM layer 410. The heat slug 420 may include a material having excellent thermal conductivity, for example, aluminum (Al), gold (Au), silver (Ag), copper (Cu), iron (Fe), graphite, graphene, or the like. In the semiconductor package 100D according to the present example embodiment, the heat dissipation member 400 may be mounted on an upper portion of the first chip structure 200, thereby improving thermal properties.

According to example embodiments of the present inventive concept, back side power delivery system may be introduced to a lower semiconductor chip of a chip structure, such that a semiconductor package may have improved voltage properties.

While example embodiments have been shown and described above, it will be apparent to those skilled in the art that modifications and variations could be made without departing from the scope of the present inventive concept as defined by the appended claims.

What is claimed is:

1. A semiconductor package comprising:
a package substrate having an upper surface and a lower surface opposing each other;
a first chip structure on the upper surface of the package substrate, the first chip structure including a first semiconductor chip, a second semiconductor chip on the first semiconductor chip, connection bumps electrically connecting the first and second semiconductor chips to each other, and an adhesive layer covering at least a portion of the connection bumps, between the first and second semiconductor chips; and
a second chip structure spaced apart from the first chip structure, on the upper surface of the package substrate,
wherein the first semiconductor chip has a first front surface and a first back surface opposing each other,
the first semiconductor chip includes:
a first front circuit layer and a first back circuit layer respectively disposed adjacent to the first front surface and the first back surface;
first front connection pads and first back connection pads respectively on upper portions of the first front surface and the first back surface; and
through-electrodes including a first through-electrode electrically connecting the first front circuit layer and the first back circuit layer to each other, and a second through-electrode electrically connecting at least a portion of the first front connection pads and the first back circuit layer to each other,
the second semiconductor chip has a second front surface opposing the first front surface, and
the second semiconductor chip includes a second front circuit layer disposed adjacent to the second front surface, and second front connection pads on the second front surface.

2. The semiconductor package of claim 1, wherein the first chip structure further includes an encapsulant covering at least a portion of a side surface of the second semiconductor chip.

3. The semiconductor package of claim 1, wherein the second chip structure includes at least one memory chip.

4. The semiconductor package of claim 1, wherein a width of the first semiconductor chip in a horizontal direction is greater than a width of the second semiconductor chip in the horizontal direction.

5. The semiconductor package of claim 4, wherein the second semiconductor chip includes a plurality of second semiconductor chips disposed on the first semiconductor chip to be spaced apart from each other in the horizontal direction.

6. The semiconductor package of claim 1, wherein a height of the first through-electrode is lower than a height of the second through-electrode.

7. The semiconductor package of claim 1, wherein the first front circuit layer surrounds at least a portion of a side surface of the second through-electrode.

8. The semiconductor package of claim 1, wherein a height of the first chip structure is higher than a height of the second chip structure.

9. The semiconductor package of claim 8, wherein a height of the second semiconductor chip is higher than a height of the first semiconductor chip.

10. The semiconductor package of claim 1, wherein the package substrate is an organic substrate.

11. The semiconductor package of claim 1, wherein the first semiconductor chip is a back side power distribution network (BSPDN) chip.

12. The semiconductor package of claim 1, wherein the first chip structure further includes a protective layer covering at least a portion of each of the first front surface and the second front surface.

13. The semiconductor package of claim 1, further comprising:
a heat dissipation member on the first chip structure.

14. The semiconductor package of claim 1, wherein a diameter of the first through-electrode and a diameter of the second through-electrode are the same.

15. The semiconductor package of claim 14, wherein the diameter of the first through-electrode and the diameter of the second through-electrode are 5 μm or less.

16. A semiconductor package comprising:
a package substrate having a surface, the surface having a first side and a second side opposite the first side;
a first chip structure on the surface of the package substrate and adjacent to the first side of the surface, the first chip structure including a first semiconductor chip and a second semiconductor chip stacked on the first semiconductor chip; and
a second chip structure on the surface of the package substrate and adjacent to the second side of the surface, the second chip structure spaced apart from the first chip structure,
wherein the first semiconductor chip includes a first substrate, a first front circuit layer on the first substrate, the first front circuit layer including a first integrated circuit, and a plurality of through-electrodes, including first through-electrodes and second through-electrodes, passing through the first substrate,
wherein the second semiconductor chip includes a second front circuit layer disposed toward the first front circuit layer of the first semiconductor chip, the second front circuit layer including a second integrated circuit,
wherein a portion of the first through-electrodes is configured to transmit power and ground signals of the first integrated circuit, and
wherein the second through-electrodes are configured to transmit power and ground signals of the second integrated circuit.

17. The semiconductor package of claim 16, wherein another portion of the first through-electrodes is configured to transmit an input/output signal of the first integrated circuit.

18. A semiconductor package comprising:
a first semiconductor chip including a first front circuit layer and a first back circuit layer respectively disposed adjacent to a first front surface and a first back surface opposing each other, a plurality of first front connection pads and first back connection pads respectively on the first front circuit layer and the first back circuit layer, a plurality of first through-electrodes electrically connected to the first back circuit layer, and a plurality of second through-electrodes electrically connected to the first back circuit layer;
a second semiconductor chip including a second front circuit layer disposed adjacent to the first front circuit layer of the first semiconductor chip, and a plurality of second front connection pads disposed on the second front circuit layer;
first connection bumps disposed between the first front connection pads and the second front connection pads; and
an adhesive layer between the first and second semiconductor chips, the adhesive layer covering at least a portion of each of the first semiconductor chip, the second semiconductor chip, and the first connection bumps; and
second connection bumps below the first semiconductor chip,
wherein the first semiconductor chip is configured to receive power through the plurality of first through-electrodes,
the second semiconductor chip is configured to receive power through the plurality of second through-electrodes, and
a pitch of the second connection bumps is greater than a pitch of the first connection bumps.

19. The semiconductor package of claim 18, wherein the pitch of the second connection bumps is 75 μm to 200 μm.

20. The semiconductor package of claim 18, wherein the first front connection pads and the second front connection pads have the same pitch.
